(19) United States
(12) Patent Application Publication
(10) Pub. No.: US 2009/0109786 A1
(43) Pub. Date: Apr. 30, 2009

(54) DATA MANAGEMENT METHOD FOR NON-VOLATILE MEMORY DEVICE

(76) Inventors: Kyung-Wook Ye, Seoul (KR); Yul-Won Cho, Seoul (KR)

Correspondence Address: F. CHAU & ASSOCIATES, LLC, 130 WOODBURY ROAD, WOODBURY, NY, 11797, US

(21) Appl. No.: 12/256,319

(22) Filed: Oct. 22, 2008

(30) Foreign Application Priority Data
Oct. 25, 2007 (KR) 10-2007-0107909

(51) Int. Cl. G11C 5/14; G06F 12/00; G06F 12/02

(52) U.S. Cl. 365/228; 711/103; 707/200; 707/E17.044; 711/E12.008

(57) ABSTRACT

A method of operating a non-volatile data storage device includes determining the type of the previous power off event when the non-volatile data storage device is rebooted; and selecting and performing a reboot sequence based upon the determined type of the power off event. Determining the type of the previous power off event may be performed by analyzing one or more metadata groups stored in the non-volatile data storage device. During normal operation of the data storage device a preamble (indicating that an operation of a data storage device started) and a postamble (indicating that an operation of the data storage device ended) are written in each group of metadata. If the power off event is a sudden (abnormal) power off event during a write operation, the postamble is not written, and its absence indicates that the power off event was a sudden (abnormal) power off event.

### CROSS-REFERENCE TO RELATED APPLICATIONS

This U.S. non-provisional patent application claims priority, under 35 U.S.C. §119, of Korean Patent Application No. 10-2007-0107909, filed on Oct. 25, 2007, the entire contents of which are hereby incorporated by reference herein.

### BACKGROUND OF THE INVENTION

1. Field of the Invention

The present invention disclosed herein relates to a data storage device, and more particularly, to a method for effectively managing a non-volatile memory device.

2. Description of the Related Art

Memory devices are generally divided into two classes: volatile memory devices and nonvolatile memory devices. The volatile memory devices are typically semiconductor memory devices that have a high read/write speed but lose stored data when power supply thereto is interrupted. On the other hand, the nonvolatile memory devices can retain stored data even when power supplied thereto is interrupted. Therefore, the nonvolatile memory devices are used to store data that must be retained regardless of power supply.

Examples of nonvolatile semiconductor memory devices are mask read-only memories (MROMs), programmable read-only memories (PROMs), erasable programmable read-only memories (EPROMs), and electrically erasable programmable read-only memories (EEPROMs). Flash memory is a specific type of EEPROM (Electrically Erasable Programmable Read-Only Memory) that is erased and programmed in entire “blocks”. Flash memories have a function of electrically erasing data of cells in a “batch” manner. Flash memories are widely used in computers and memory cards. Recently, flash memory has become the dominant technology wherever a significant amount of non-volatile, solid-state storage is needed. Common applications include PDAs (personal digital assistants), laptop computers, digital audio players, digital cameras and mobile phones. It has also gained popularity in the game console market, where it is often used instead of EEPROMs or battery-powered SRAM for game save data. High capacity flash memories are now widely used as primary computer data storage devices instead of hard disk drives.

In comparison with other memory devices, a flash memory is advantageous in that it can provide a high read speed at a relatively low unit cost. However, the flash memory is characterized by a block erase operation must be performed beforehand in order to write data therein and the block data erase time is greater than its data write time. These characteristics make it difficult to use the flash memory as a main system RAM (random access memory), and also hinders the use of a conventional hard-disk file system even when the flash memory is used as an solid state drive (SSD). Thus, a flash translation layer (FTL) is used between the file system and the flash memory to hide the erase operation of the flash memory. Flash memory devices are widely used not only as data storages but also as code storages that store data that must be retained regardless of power supply. Flash memory devices can be used for code storage in mobile devices (e.g., cellular phones, PDAs, digital cameras, portable game consoles, and MP3Ps) and also in home applications (e.g., HDTVs, DVD players, routers, and GPS units).

Due to an address mapping function of the FTL, a host can recognize a flash memory device as a hard disk drive (or, SRAM), and it allows the host to access the flash memory device through the same method as a hard disk drive. The FTL may be realized with a hardware form separated from a host system, or may be realized with a device driver form in a host system.

The flash translation layer (FTL) performs functions such as management of logical address-to-physical address mapping information, management of bad blocks, management of data protection against unexpected power interruption, and wear leveling. For example, in a write operation of the flash memory, the FTL serves to map a logical address, which is generated by the file system, to a physical address of the flash memory that has beforehand performed an erase operation. The FTL uses an address mapping table for rapid address mapping. The flash translation layer (FTL) specification allows a flash device to look to a host computer like a hard disk drive, but still have effective wear leveling. The address mapping function of the FTL enables a host to recognize a flash memory device as a hard disk drive (or as an SRAM) and to access the flash memory device in the same way as for the hard disk drive. Newer NAND flash chips have pages comprising 2048 bytes+64 bytes spare areas, and strict write requirements. Each block contains 32 pages. Each page within a memory block must be written to in sequential order, and each page must be written only once.

The flash memory device may face a situation in which rebooting is required due to a serious error during a memory access operation. One example is a power error (e.g., interruption of electric power). This kind of a power error is called sudden power off. If sudden power off occurs during a programming operation, a writing error occurs in a memory cell on which a program operation is performed. This writing error may corrupt user data and/or metadata. However, the conventional FTL cannot distinguish normal power off (i.e., a user cut off the power source under a normal circumstance) from sudden power off (i.e., battery separation or drained battery power). Accordingly, a designer needs to design the flash memory device to perform a reboot sequence in order to guarantee system stability by assuming a sudden power off of the worst case. Thus, the FTL allocates a new memory block and performs an erase operation upon the new memory block each time a reboot sequence is performed, and then performs an operation for programming user data and/or metadata on the erased pages of the new memory block.

The performing of the erase operation upon a new memory block increases the booting time of a flash memory device and increases a wear count value affecting the flash memory device. The increased wear count value reduces the life time of the flash memory device and a system using the flash memory device. The FTL performs wear leveling for uniformly selecting a new memory block by considering the increased wear count value. However, this merely causes the wear count value of the flash memory device to be uniformly distributed, but does not eliminate the wear value increase issue.

### SUMMARY OF THE INVENTION

Aspects of the present invention provides a method of data management of a non-volatile memory device that recognizes and distinguishes between a normal power off and a sudden involuntary power off and performs respectively different reboot sequences based on a recognition result.

An exemplary embodiment of the invention provides a new data management method including a metadata group having “open” metadata (indicating that an operation of a data storage device started) and “closed” metadata (to indicate that an operation of the data storage device ended). The term “open metadata” refers to a preamble (e.g., prefix, header) to be stored in a first or in multiple pages at the beginning of each group of metadata (metadata group). The term “‘closed’ metadata” refers to a postamble (e.g., postfix) to be stored in the last or in multiple pages at the end of each group of metadata (metadata group). Each postamble may have the form of multi-bit stored throughout an entire page of a memory block of the non-volatile memory. The preamble page and the postamble page may be termed “open” and “closed” respectively, or instead “start” and “stop”, or “begin” and “end” or as an other pair of complementary terms. Each of the preamble metadata and the postamble metadata may be encoded bits in the memory space of one page of the memory block or each may be a short word or a long word within a page.

Each time the data storage device is booted up (rebooted), the data management method analyzes the metadata groups in order to determine the type of the previous power off event and then selects and performs a different booting operation based on the determined type of power off event.

Another embodiment of the present invention provides a data management method of a non-volatile memory device for preventing an error of programming data on a soft programmed page.

Another embodiment of the present invention provides a data management method of a non-volatile memory device capable of prolonging a life time of a non-volatile memory device by minimizing a count value increase during rebooting.

Another embodiment of the present invention provides a data management method of a non-volatile memory device having an improved booting speed.

Embodiments of the present invention provide data management methods including the following steps: determining a type of previously performed power off by analyzing one or more metadata groups when a data storage device is rebooted; and performing a reboot sequence defined differently depending upon the determined type of the power off, wherein the stored metadata group includes “open” metadata for indicating that an operation of the data storage device started. If the stored metadata group includes a “closed” metadata (indicating that an operation of the data storage device ended normally), then an accelerated reboot sequence is performed. If the stored metadata group does not include a “closed” metadata for indicating that an operation of the data storage device ended normally, then a reboot sequence appropriate for recovering from a sudden power off is performed.

In some embodiments, a plurality of “open” metadata are stored in the metadata group.

In some embodiments, the plurality of “open” metadata have the same data value.

In some embodiments, “open” metadata having highest reliability among the plurality of “open” metadata are analyzed during the rebooting.

In some embodiments, the last stored “open” metadata among the plurality of “open” metadata is analyzed during the rebooting.

In other embodiments, “open” metadata remote from other metadata groups among the plurality of “open” metadata are analyzed during the rebooting.

In some embodiments, the “open” metadata are stored being spaced a predetermined distance apart from “closed” metadata of other metadata groups.

In some embodiments, the metadata group includes a plurality of “open” metadata, at least one of other metadata, and the “closed” metadata.

In other embodiments, the at least one other metadata is stored by a predetermine distance apart from the “open” metadata.

In some embodiments, if at least one of the “open” metadata and the “closed” metadata is not stored according to an analysis result of the metadata group, then it is determined that sudden power off occurs.

In some embodiments, if it is determined that the sudden power off had occurred, a new memory block is selected and erased in the data storage device during the rebooting and a new metadata group is stored in the erased memory block.

In some embodiments, if the “open” metadata and the “closed” metadata are stored and no data are stored after the “closed” metadata according to an analysis result of the metadata group, it is determined that normal power off process was performed.

In some embodiments, if it is determined that the normal power off process was performed, the reboot sequence performed will not include select and erase operations for allocating a new memory block in the data storage device.

In some embodiments, if it is determined that the normal power off process was performed, an existing memory block including the metadata group is first used after the rebooting.

In some embodiments, the data storage device is a non-volatile memory.

In some embodiments, the data storage device and a memory controller constitute a solid state drive/disk (SSD).

In some embodiments, the metadata group is configured and managed by a flash translation layer.

Hereinafter, exemplary embodiments of the present invention will be described in detail with reference to the accompanying drawings. The structure and operation of exemplary circuits and methods according to embodiments of the present invention will be described with reference to the accompanying drawings. The present invention may, however, be embodied in different forms and should not be construed as limited to the embodiments set forth herein. Rather, these exemplary embodiments are provided so that this disclosure will be thorough and complete, and will fully convey the scope of the present invention to those skilled in the art.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a block diagram of a data storage device according to an exemplary embodiment of the present invention and a non-volatile memory system including the data storage device;

FIG. 2A and 2B are block diagrams of a data group including a plurality of pages in a memory block of a nonvolatile memory for illustrating a method of writing metadata including an “open/closed” metadata group according to an exemplary embodiment of the present invention;

FIG. 3A and 3B are block diagrams of a plurality of pages in a memory block for illustrating a data storage method wherein an “open/closed” metadata group of FIG. 2A is continuously written into another metadata group;

FIGS. 4A and 4B are block diagrams of a plurality of pages in a nonvolatile memory device for illustrating a data storage method wherein an “open/closed” metadata group of FIG. 2B is continuously written into another metadata group;

FIGS. 5A through 5C are block diagrams of various metadata groups in a nonvolatile memory device for illustrating a method of identifying a sudden power off event according to an exemplary embodiment of the present invention;

FIG. 6A is a block diagram illustrating a data management method for preventing data from being written in a soft programmed page, and also soft program errors that occur during sudden power off; FIGS. 6A and 6B are a block diagrams of pages in a nonvolatile memory device for illustrating soft program errors that occur during sudden power off and a data management method for preventing data from being written in a soft programmed page, according to an exemplary embodiment of the present invention.

FIG. 7 is a block diagram of a computing system including a data storage device according to the present invention.

### DETAILED DESCRIPTION OF PREFERRED EMBODIMENTS

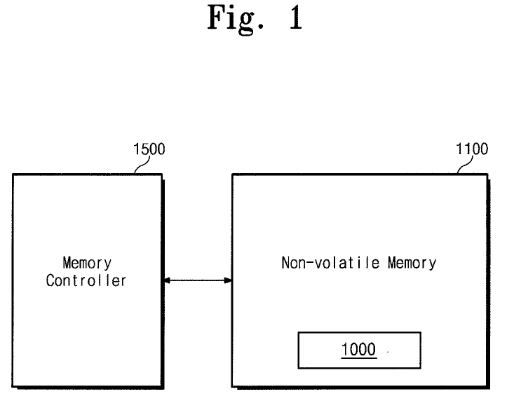

FIG. 1 is a block diagram of a data storage device 1100 and a non-volatile memory system including the data storage device 1100 according to an exemplary embodiment of the present invention.

The data storage device 1100 includes a memory cell array 1000 formed of a plurality of non-volatile memory cells (not shown individually). The memory cell array 1000 may include flash memory cells, however, it will be apparent to those skilled in the art that the present invention can be applied to other kinds of non-volatile memory devices. Additionally, the physical structures of the memory cell array 1000, the number of the memory cell arrays 1000, the form of the memory cell array 1000, and the configuration (e.g., the number of bits to be stored in each cell, types of a memory cell, etc.) of each memory cell constituting the memory cell array 1000 are not limited and may vary.

Referring to FIG. 1, the data storage device 1100 and the memory controller 1500 together constitute the non-volatile memory system. The non-volatile memory system of FIG. 1 may constitute a memory card and/or a memory card system (e.g., memory card reader and memory card), or a solid state drive/disk (SSD), or a hybrid drive using a non-volatile memory for storing data.

The memory controller 1500 is configured to communicate with an external host (e.g., computer system, not shown) via a known interfaces such as a universal serial bus (USB), a multi-media card (MMC), peripheral component interface (PCI)-E, advanced technology attachment (ATA), serial-ATA, parallel-ATA, a small computer system interface (SCSI), SAS(Serial Attached SCSI), an enhanced small disk interface (ESDI), and integrated drive electronics. The memory controller 1500 controls the data storage device 1100 when an access for the data storage device 1100 is requested from the host. For example, the memory controller 1500 controls a read/write/erase operation of the data storage device 1100. Moreover, the memory controller 1500 manages mapping information of the data storage device 1100 to allow the host to utilize the data storage device 1100 as a storage medium in which a read/write/erase operation is performed without access restrictions like as if it were an SRAM or a hard disk drive HDD. The mapping information of the data storage device 1100 may be managed by a file translation layer, for example, FTL (flash translation layer). In the present invention, the FTL applied to a flash memory is used in exemplary embodiments including flash memories. However, it is apparent to those skilled in the art that the file translation layer applied to the present invention is not limited to the FTL.

The FTL may be implemented in hardware form separated from a host system or with a software form as a device driver in the host computer system. A mapping result performed by the FTL is stored as metadata. The metadata includes various additional information that will be provided to a user in addition to an address mapping result of the FTL. The metadata may be stored in a specific region of the memory cell array 1000 in the data storage device 1100 or may be uniformly distributed the entire memory cell array 1000. Therefore, a region where metadata are stored may be realized in various forms in the memory cell array 1000.

As will be illustrated in greater detail below, the FTL manages the recording (storage) of a “open” metadata (indicating that an operation of the data storage device 1100 started (i.e., power on)) and a “closed” metadata (indicating that the operation of the data storage device 1100 ended (i.e., power off)) among the metadata. When the data storage device 1100 is booted up (e.g., rebooted after a power off event), the FTL analyzes the recorded state of the “open” metadata and the corresponding “closed” metadata. Then, the FTL determines whether normal power off or sudden power off (due to memory device removal, battery separation or drained battery power) had occurred in the data storage device 1100. The FTL selects and initiates different types of reboot sequence, each time a power off operation is performed, depending upon the result of analyzing the recorded “open” and “closed” metadata. By selecting the appropriate reboot sequence, the boot time consumed by a reboot sequence can be reduced and an increase of a wear count value can be minimized during the rebooting. Accordingly, the life time of a non-volatile memory device may be prolonged, and an error of programming data on a soft programmed page during sudden power off can be prevented.

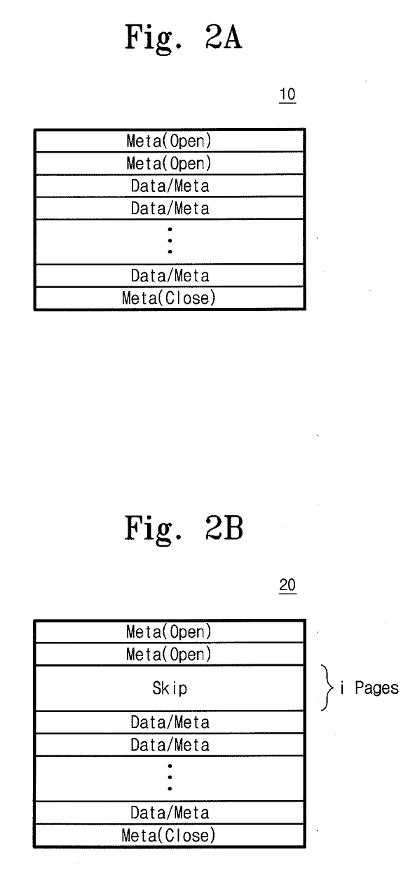

FIG. 2A and 2B are block diagrams of a data group including a plurality of pages in a memory block of a nonvolatile memory for illustrating a method of writing metadata including an “open/closed” metadata group according to an exemplary embodiment of the present invention. FIG. 2A and 2B illustrates a data write into an arbitrary memory block of the memory cell array 1000 in the data storage device 1100. It is apparent to those skilled in the art that the data storage method of the present invention that will be described below is not limited to any particular memory block of the memory cell array 1000. The recording and management of data to be described below is performed through the FTL.

Referring to FIG. 2A, once the data storage device 1100 starts to operate (i.e., with adequate power supply), the “open” metadata in a selected memory block are written adjacently at least twice. Here, each “open” metadata have the same data value. Then, user data and/or metadata are recorded. The “closed” metadata are written in the selected memory bock when the operation of the data storage device 1100 ended normally. When power is shut off normally, an operating system (not shown) notifies all processors of the fact that power is to be cut off through an interrupt signal or other signal. The FTL analyzes the interrupt signal or other signal provided from the operating system and, based on the analyzing the signal, recognizes the fact that power imminently will be turned off. Consequently, the FTL has the opportunity to record the “closed” metadata before the power is turned off. If the data storage device 1100 does not power-off normally (e.g., does not receive the interrupt signal or other signal provided from the operating system), the “closed” metadata are not written into a corresponding memory block.

FIG. 2A illustrates a case where “open” metadata are written adjacently twice (i.e., double redundancy repetition). However, the number of “open” metadata recorded may vary (e.g., it may be the natural number k, such that k is equal to or greater than 2). For convenience of explanation, a data group 10 of FIG. 2A storing “open” metadata and corresponding “closed” metadata and other user data or metadata in between is defined as a metadata group. The “open” metadata may be written plural times in each metadata group which serves to prevent an error of programming data into a soft programmed page that is not easily identified by only a read operation. Accordingly, the probability that an error correction code (ECC) error may occur is reduced and data accuracy of the data storage device 1100 is increased.

Referring to FIG. 2b, a variation on the data group 10 of FIG. 2A is shown.

The “open” metadata are recorded twice, as in FIG. 2A. Then, after skipping a number i (i is a natural number equal to or greater than 0) of pages from the last stored “open” metadata, user data/metadata is stored. Next, after the user data/metadata are sequentially written, the “closed” metadata are finally written. The “closed” metadata are written only if the data storage device 1100 is turned off normally (e.g., by a user).

In various embodiments, the “open” metadata (preamble) may be the 2's complement of the “closed” metadata (postamble) such that a simple addition or subtraction comparison operation will detect the presence of both valid “open” metadata (preamble) and valid “closed” metadata (postamble) in any given metadata group. In such embodiments, wherein the preamble and postamble are 2's complements or otherwise logically related, the bits in each preamble may be otherwise arbitrary, and the bits in the postamble may be otherwise arbitrary. Thus, the bits of “open” metadata (preambles) in different metadata groups may be different and/or the bits of “closed” metadata (postamble) in different metadata groups may be different. Thus, one page of ordinary metadata or one page of user data may be stored (encoded) within each corresponding pair of “open” metadata (preamble) and “closed” metadata (postamble). In other embodiments, the bits of the “open” metadata and of the “closed” metadata in a given metadata group may be logically independent of each other. In various embodiments, the value of each “open” metadata (preamble) and of each “closed” metadata (postamble) may be logically related to payload data (e.g., metadata and/or user data) stored in between corresponding “open” metadata (preamble) and “closed” metadata (postamble) in a given metadata group. In some embodiments, at least one of the “open” metadata (preamble) and “closed” metadata (postamble) may comprise parity bits that are logically related to the bits of the stored payload data (e.g., metadata and/or user data) stored in between corresponding “open” metadata (preamble) and “closed” metadata (postamble) in each given metadata group. In some exemplary embodiments, the “open” metadata (preamble) of one metadata group may have a predetermined logical or mathematical relationship with the “closed” metadata (postamble) in a preceding metadata group. In some exemplary embodiments, the “open” metadata (preamble) of one metadata group may have a predetermined logical or mathematical relationship with the “open” metadata (preamble) in a preceding metadata group. In other embodiments wherein there are two “open” metadata (preambles) and one “closed” metadata (postamble) in each metadata group, one of the “open” metadata (preamble) may comprise parity bits logically related to the payload data of a metadata group, and the second “open” metadata (preamble) may be logically related (e.g., the 2's complement) of the first “open” metadata (preamble).

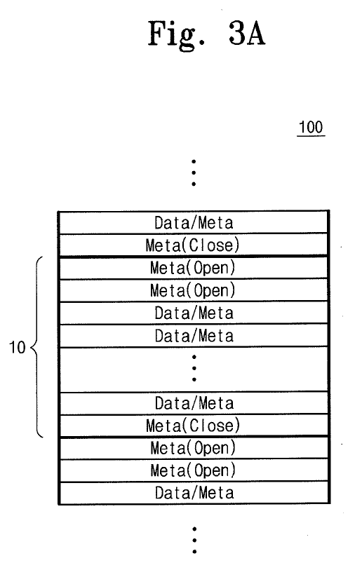

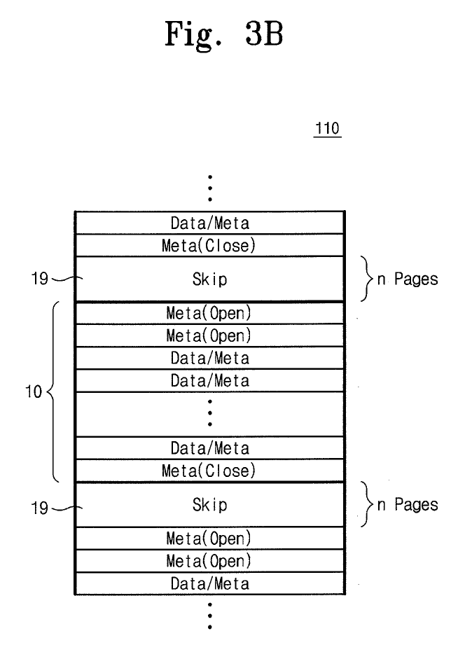

FIG. 3A and 3B are block diagrams of a data group including a plurality of pages in a memory block for illustrating a data storage method wherein an “open/closed” metadata group of FIG. 2A is continuously written into another metadata group.

FIG. 3A and 3B illustrate a data storage method when the metadata group 10 of FIG. 2A is continuously written into another metadata group.

Referring to FIG. 3A, the metadata group 10 of FIG. 2A may be continuously written into another adjacent metadata group. In this case, no empty page is additionally allocated between the metadata groups.

In FIG. 3B, an interval between metadata groups is labeled by reference numeral 19 in FIG. 3B. Each metadata group 10 begins number n of (skipped) pages after the end of the previous metadata group An interval of n pages, wherein n is an integer equal to or greater than 0 exists between each metadata group. The number n of skipped pages between metadata groups may vary.

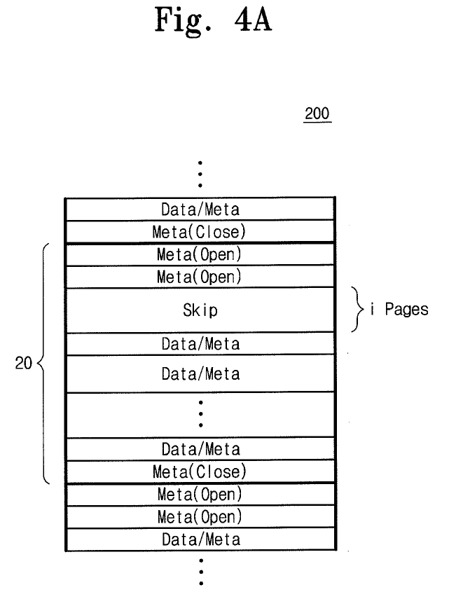

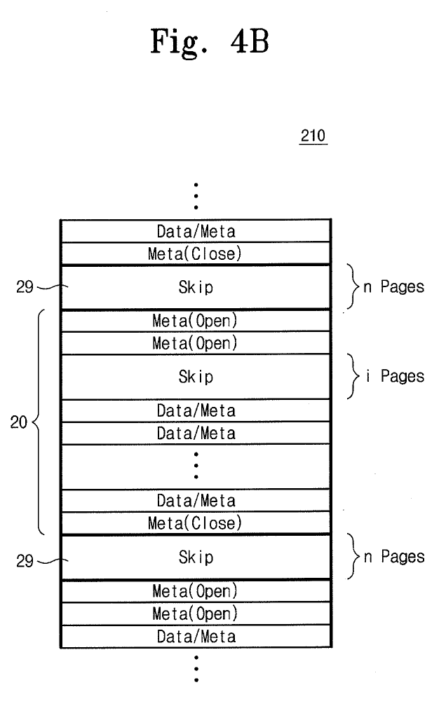

FIGS. 4A and 4B are block diagrams of a data group including a plurality of pages in a memory block for illustrating a data storage method wherein the metadata group 20 of FIG. 2B is continuously written into another metadata group.

Referring to FIG. 4A and 4B, the metadata group 20 of FIG. 2B may be continuously stored into the next adjacent metadata group. Or, the metadata group 20 of FIG. 2B may be stored into a metadata group after skipping n pages (i.e., after an interval of n skipped pages) from the previous data stored another metadata group. An interval of n skipped pages between the metadata groups is shown as a reference numeral 29 in FIG. 4B. The number n of skipped pages between metadata groups may vary.

Variations of the data included in each metadata group and of usages of pages between metadata groups may be employed. For example, an “open” metadata may be written in more than 2 pages (e.g., k is an integer equal to or greater than 2) within each metadata region. Moreover, the position within each metadata region where the “open” metadata are to be written may be the next page adjacent to the “closed” metadata of the previous metadata group, or may be a page remote from the “closed” metadata of the previous metadata group by n pages (n is an integer equal to or greater than 0). Furthermore, after the “open” metadata is written, the next user data or metadata (e.g., “open” metadata) can be written after skipping the i number of pages (i is an integer equal to or greater than 0). Thus, FIGS. 2A through 4B simply illustrate various embodiments of the data storage method according to the present invention. It is apparent to those skilled in the art that the present invention is not limited to the above mentioned embodiments.

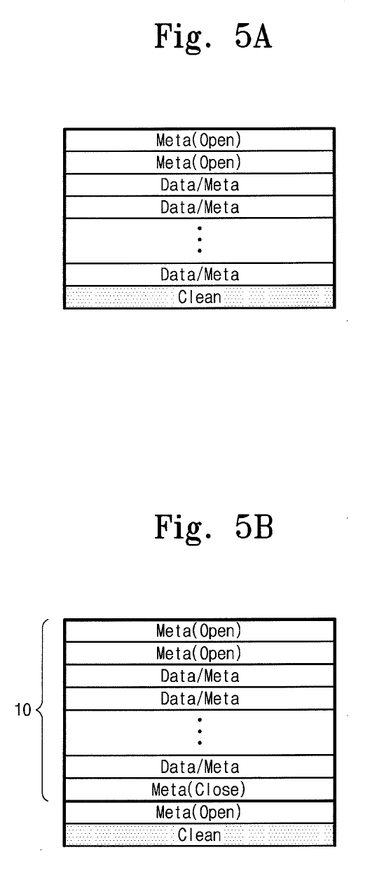

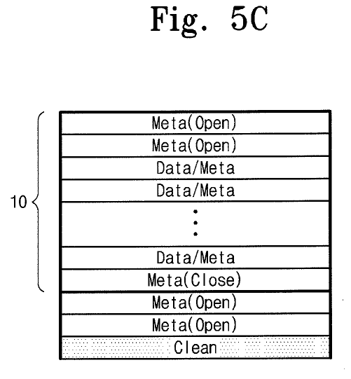

FIGS. 5A through 5C are block diagrams of pages in a nonvolatile memory device for illustrating a method of identifying a sudden power off event based on examining the contents of a metadata group according to an exemplary embodiment of the present invention.

Referring to FIG. 5A, two “open” metadata and a plurality of user data and other metadata are written in a metadata group 10, but corresponding “closed” metadata are not written therein. This means that the data storage device 100 was not turned off normally but was turned off abnormally. If the contents of a metadata group is like FIG. 5A (without containing corresponding “closed” metadata), an FTL performs a reboot sequence appropriate for recovering from the sudden power off. The reboot sequence appropriate for recovering from the sudden power off typically means that when the power source is reapplied to the data storage device 1100 a new memory block is allocated and an erase operation is performed therein and then user data and/or metadata are written into the erased page. The written metadata will include “open” metadata, “closed” metadata, an address mapping result of FTL, and other additional data.

A plurality of metadata groups may be stored in the memory cell array 1000 of the data storage device 1100. The FTL distinguishes between different types of power off through an analysis of the most recently stored metadata group during rebooting. Then, a reboot sequence based upon a determination of either a sudden power off or abnormal power off is performed based on the result of analyzing the stored metadata. The simple structure of the metadata group 10 of FIG. 2A has been be used as one example to describe a reboot sequence of the data storage device 1100. However, operational characteristics of the present invention that will be described below are applicable not only to the exemplary metadata group 10 and to the metadata group 20, but also to metadata of various other forms.

Referring to FIG. 5B and 5C, two “open” metadata and one corresponding “closed” metadata are stored in one metadata group 10, but the subsequent metadata group contains only “open” metadata.

In FIG. 5B only one “open” metadata is written in the next page after the “closed” metadata of the prior metadata group 10, and the next page reserved for the expected second “open” metadata does not contain the expected second “open” metadata. This indicates that power was suddenly turned off while the first “open” metadata was being written (or, after the first “open” metadata was written). In this case, the FTL performs a reboot sequence appropriate for recovering from a sudden power off.

In FIG. 5C two “open” metadata are written in the next two pages after the “closed” metadata of the prior metadata group 10, and the next page reserved for other metadata does not contain metadata (i.e., remains as a “clean” page). While there is no corresponding “closed” metadata the “clean” page indicates that power was turned off normally. In this case, the FTL performs a rapid reboot sequence appropriate for a normal power off.

If two “open” metadata and one “closed” metadata are written into one metadata group and there is no stored data nor any “open” metadata after the “closed” metadata (i.e., remains as a clean page), the FTL recognizes it as a normal power off state and performs a reboot sequence appropriate to a normal power off.

Unlike a reboot sequence following a sudden power off, a reboot sequence following a normal power off omits an operation for additionally allocating an additional memory block and an operation for erasing the allocated memory block. Therefore, during rebooting following a normal power off, “open” metadata and user data and metadata are sequentially written after the power source is reapplied. As a result, the rebooting speed is improved and the life time reduction of the memory device due to repetitive erase operations can be prevented. Thus “open” metadata are repeatedly stored k times (k is an integer equal to or greater than 2) in each metadata group, the redundant “open” metadata are used for preventing errors of writing data in a soft programmed page if any.

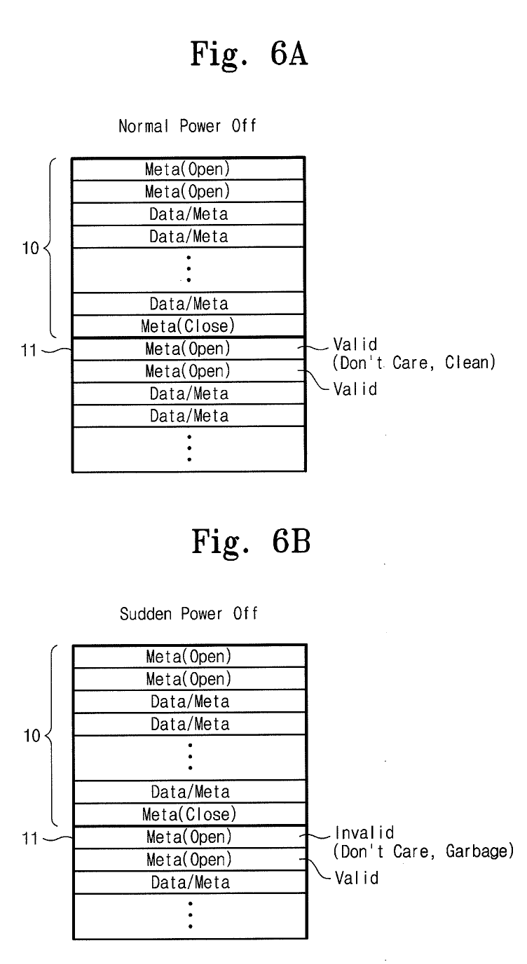

FIGS. 6A and 6B are a block diagrams of pages in a nonvolatile memory device for illustrating soft program errors that occur during sudden power off and a data management method for preventing data from being written in a soft programmed page, according to an exemplary embodiment of the present invention. If power is turned off when data are being written into a specific page in a memory block, when that page is read during rebooting, the contents of the page may be read as a clean page or as garbage value. An interesting fact is that each time this page is read, its read result can be different. It may be read as a clean page or as page where a garbage value is written. The above-mentioned page is called a soft programmed page. If power is turned off when specific data are about to be written in a memory page and this affects a corresponding page, it is called “soft programmed”.

When the first data are stored after rebooting, it is necessary to guarantee that the page recognized as a clean page in read operation is not a soft programmed page. In the case of a soft programmed page, even though it may be read as a clean page, if data are written in it, the written data will be damaged and ECC errors occur during the next read operation. This problem may occur also when “open” metadata are written in the next page after a valid “closed” metadata.

If (two) “open” metadata and a corresponding “closed” metadata are written as expected in every metadata group 10 in the memory block, according to the method of present invention, the FTL recognizes that as an indication that a normal power off operation was performed.

Referring to FIG. 6A, the data shown stored in pages written after the normally “closed” metadata group 10 corresponds to a normal power off. In this case, the data stored in page 11 after the “closed” metadata of the metadata group 10 is in a clean state. Therefore, data stored in a corresponding page 11 and pages stored thereafter are reliable and so ECC errors do not occur.

Referring to FIG. 6B, the data shown stored in pages stored after the normally “closed” metadata group 10 corresponds to a sudden (abnormal) power off. There may be occurrences in which the power is suddenly turned off while the FTL is writing the “open” metadata of a metadata group. In this case, because the “open” metadata are not normally written, and the values stored may be read as “erased” or as “clean” values, that page may be recognized as a clean page when page 11 is read. However, since a programming voltage was applied to the page 11 for a short time, a threshold voltage of at least one memory cell in page 11 may have been arbitrarily changed. This means that an unwanted garbage value may be stored in page 11.

To prevent the above, the preferred methods of the present invention write “open” metadata at least twice in each metadata group, and analyzes and manages data by using “open” metadata (e.g., the last stored “open” metadata) mitigating the possibility of soft program error occurrence among written metadata. Additionally, according to the present invention, “open” metadata and user data/metadata may be stored being spaced apart from each other (see FIGS. 2B and) with an interval of a predetermined number n of pages in order to effectively prevent an error of writing data in a soft programmed page. Moreover, new “open” metadata may be stored spaced apart from “closed” metadata of the previously stored another metadata block with an interval of the n pages (see FIGS. 3B and 4B).

According to the metadata storage method of the present invention, even if soft program errors unidentified by only a read operation occur in a memory block, because the FTL modified according to embodiments of the present invention uses the most reliable “open” metadata among a plurality of “open” metadata, it is not affected by a soft program error. Here, the reliable “open” metadata may be “open” metadata stored being spaced part from the previous metadata group by an interval of a predetermined number n or pages. Alternatively, the reliable “open” metadata may be the “open” metadata that were lastly stored among the plurality of stored “open” metadata. Therefore, accurate analysis and management of “open” metadata is possible.

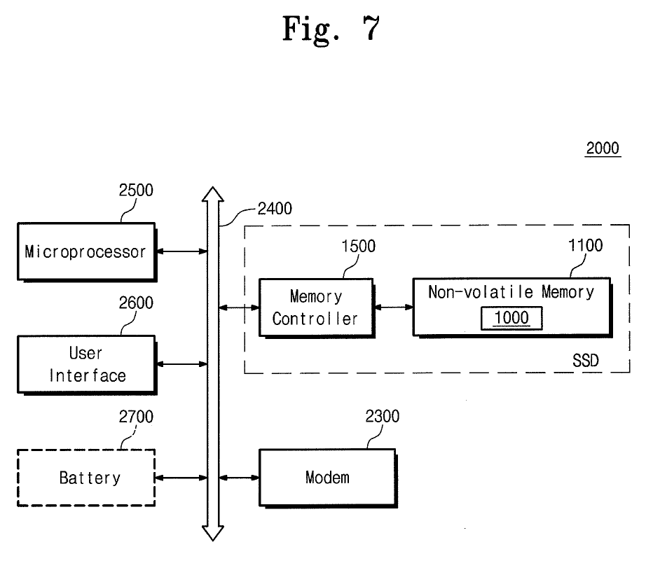

FIG. 7 is a block diagram of a computing system 2000 including a data storage device 1100 according to an embodiment of the present invention.

Referring to FIG. 7, the computing system 2000 includes a data storage device 1100, a memory controller 1500, a modem 2300 such as a baseband chipset, a microprocessor 2500, and a user interface 2600, which are electrically connected through a system bus 2400. The data storage device 1100 of FIG. 7 may have the same structure as the of FIG. 1. B-bit data (wherein B is an integer equal to or greater than 1) to be processed by the microprocessor 2500 are stored in the data storage device 1100 and accessed through the memory controller 1500. The data storage device 1100 and the memory controller 1500 of FIG. 7 may constitute a solid state drive/disk (SSD). The data storage device 1100 composes a metadata group according to the above-disclosed method and upon a power off and subsequent reboot sequence the FTL analyses the stored metadata groups and determines whether the power off was a normal power off or a sudden power off.

During rebooting, FTL of the data storage device 1100 of the present invention analyzes “open” metadata and “closed” metadata stored in the last stored metadata group in order to determine whether the power off event was a normal power off or sudden power off. For example, during rebooting if the FTL determines that the power off event was a sudden power off, a new memory block is allocated and then an erase operation is performed thereon. On the other hand, if the FTL determines that the power off event was a normal power off, an allocate operation for a new memory block and an erase operation are omitted. A new metadata group may be immediately written into an existing selected memory block.

When a new metadata group is written according to embodiments of the present invention, “open” metadata are stored in the first k pages (k is an integer equal to or greater than 2) of each metadata group. Then, when the “open” metadata are read later, the most reliable “open” metadata (i.e., the last stored “open” metadata or the “open” metadata spaced apart from a proceeding metadata group among a plurality of “open” metadata) are read. As a result, memory devices of the present invention are not adversely affected by soft program errors due to unwanted power errors that would not be identified by only a read operation. The booting time consumed by a rebooting can be reduced and an increase of the wear count value can be minimized during rebooting. Therefore, the life time of a non-volatile memory device can be extended. An error due to a soft programmed page written during sudden power off can be prevented.

If the computing system 2000 according to the present invention is a mobile device, a battery 2700 is additionally provided in order to supply an operating voltage of the computing system 2000. Although not shown in FIG. 7, it will be apparent to those skilled in the art that an application chipset, a camera image processor (CIS), a mobile DRAM may be further provided to the computing system 2000.

A flash memory device and/or a memory controller according to the present invention may be packaged using various types of packages. Examples of the packages include package-on-package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP), wafer-level processed stack package (WSP), etc. According to exemplary embodiments of the present invention, memory cells are implemented using one of various known cell structures having a charge storage layer.

According to exemplary embodiments of the present invention, a power off event is detected and classified into a normal power off operation and a sudden power off event. Depending upon the classification of a power off event, different booting operations can be performed. As a result, the booting time consumed for a rebooting can be reduced and an increase of a wear count value during rebooting can be minimized. Therefore, the life time of a non-volatile memory device can be extended. Moreover, an error of programming data on a soft programmed page can be prevented after a sudden power off occurs.

The above described exemplary embodiments are to be considered illustrative, and not restrictive, and the appended claims are intended to cover all modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of operating a non-volatile data storage device comprising:
determining the type of a prior power off by analyzing an existing memory block when the data storage device is rebooted; and
performing a reboot sequence selected based upon the determined type of the prior power off.

2. The method of claim 1, wherein if it is determined that a normal power off process was performed, the reboot sequence includes storing a new metadata group in the existing memory block without erasing the existing memory block.

3. The method of claim 1, wherein determining the type of the prior power off includes when the data storage device is rebooted analyzing one or more metadata groups stored in the existing memory block; and
wherein the metadata group includes “open” metadata for indicating that an operation of the data storage device started.

4. The method of claim 1, wherein if the metadata group does not include “closed” metadata for indicating that an operation of the data storage device ended, then the selected reboot sequence performed includes selecting and erasing a new memory block.

5. The method of claim 1, wherein if the metadata group includes “closed” metadata for indicating that the started operation of the data storage device ended, then it is determined that a normal power off was performed and the selected reboot sequence performed does not include selecting and erasing a new memory block in the data storage device.

6. The method of claim 1, wherein a plurality of “open” metadata are normally stored in each metadata group.

7. The method of claim 6, wherein each of the plurality of “open” metadata have the same data value.

8. The method of claim 6, wherein the “open” metadata having the highest reliability among the plurality of “open” metadata is analyzed during rebooting.

9. The method of claim 6, wherein the last stored “open” metadata among the plurality of “open” metadata is analyzed during rebooting.

10. The method of claim 6, wherein the “open” metadata remote from other metadata groups among the plurality of “open” metadata is analyzed during rebooting.

11. The method of claim 1, wherein the first-written “open” metadata of a current metadata group is stored by a first predetermined distance apart from the “closed” metadata of the previous metadata group.

12. The method of claim 1, wherein the metadata group comprises a plurality of “open” metadata, at least one other metadata, and one “closed” metadata.

13. The method of claim 12, wherein the metadata group comprises user data and wherein at least one of the user data and the other metadata is stored by a second predetermine distance apart from the corresponding “open” metadata of the same metadata group.

14. The method of claim 1, wherein if one of the “open” metadata and the “closed” metadata are not stored in a metadata group, it is determined that sudden power off occurred.

15. The method of claim 14, wherein if it is determined that a sudden power off had occurred, a new memory block is selected and erased in the data storage device during rebooting and a new metadata group is stored in the erased memory block.

16. The method of claim 1, wherein if the “open” metadata and the “closed” metadata are stored and no data are stored after the “closed” metadata, it is determined that a normal power off was performed.

17. The method of claim 1, wherein the data storage device is a non-volatile memory.

18. The method of claim 1, wherein the metadata group is configured and managed by a flash translation layer (FLT).

19. A solid state drive (SSD) comprising the data storage device described in claim 1; and
a memory controller configured to perform the method of claim 1.

20. The solid state drive (SSD) of claim 19, wherein the memory controller implements the flash translation layer (FLT) in claim 18.
